(19) United States
(12) Patent Application Publication
(10) Pub. No.: US 2025/0379272 A1
(43) Pub. Date: Dec. 11, 2025

(54) METHOD FOR DETECTING BATTERY SWELLING

(71) Applicant: SAMSUNG SDI CO., LTD., Yongin-si (KR)

(72) Inventor: Joohyoung Lee, Yongin-si (KR)

(21) Appl. No.: 19/186,388

(22) Filed: Apr. 22, 2025

(30) Foreign Application Priority Data
Jun. 10, 2024 (KR) 10-2024-0075327

(51) Int. Cl. H01M 10/48; H01M 10/42

(52) U.S. Cl. CPC H01M 10/48; H01M 10/4264

(57) ABSTRACT

A method for detecting battery swelling includes: arranging conductors in a region of a battery cell to detect swelling of the battery cell; measuring a capacitance change amount when an arrangement of the conductors changes; and determining whether or not battery swelling has occurred by using a result of the measuring of the capacitance change amount.

### CROSS-REFERENCE TO RELATED APPLICATION

The present application claims priority to and the benefit of Korean Patent Application No. 10-2024-0075327, filed on Jun. 10, 2024, in the Korean Intellectual Property Office, the entire disclosure of which is incorporated herein by reference.

### BACKGROUND

### 1. Field

Aspects of embodiments of the present disclosure relate to a method for detecting battery swelling.

### 2 Description of the Related Art

To prevent a secondary battery from exploding, a related art method for detecting swelling uses strain sensing as a sign of pending battery explosion. However, metal-based thin-film strain sensors lack the necessary sensitivity to respond to a small change of strain, and thin-film single crystal silicon-based strain sensors have a complicated and costly manufacturing structure and methods.

### SUMMARY

Embodiments of the present disclosure provide a method for detecting battery swelling based on capacitance sensing.

Aspects and features of the present disclosure are not limited to the aforementioned aspects and features and other aspects and features may be clearly understood by those skilled in the art from the following description.

According to an embodiment of the present disclosure, a method for detecting battery swelling includes: arranging conductors in a region of a battery cell to detect swelling of the battery cell; measuring a capacitance change amount when an arrangement of the conductors changes; and determining whether or not battery swelling has occurred by using a result of the measuring of the capacitance change amount.

The conductors may be arranged in a first region, and the capacitance change amount according to an increase in a distance between the conductors arranged in the first region may be measured.

The conductors may be arranged in a second region, and the capacitance change amount according to an increase in an area of the conductors arranged in the second region may be measured.

The region at where the conductors are arranged may be an edge region of the battery cell.

A film including the conductors may be arranged in the region.

The film may be configured to adjust the capacitance change amount according to an application.

The method may further include sensing whether or not a resonator connected to a capacitance implementation unit formed of the conductors is operating.

The method may further include adjusting a gain of a variable amplifier in consideration of a result of the sensing of whether or not the resonator is operating.

According to another embodiment of the present disclosure, a system for detecting battery swelling includes: memory configured to store a program for measuring a capacitance change amount by using conductors arranged on a surface of a battery cell; and a processor configured to execute the program. The processor is configured to detect battery swelling by measuring the capacitance change amount.

The conductors may be arranged in a region of the surface of the battery cell, and a distance between the conductors may change when battery swelling occurs.

The conductors may be arranged in a region of the surface of the battery cell, and an area of the conductors may change when battery swelling occurs.

The processor may be configured to determine whether or not a resonator connected to a capacitance implementation unit formed of the conductors is operating and to adjust a gain of a variable amplifier in response thereto.

Embodiments of the present disclosure can be easily implemented by using a material (e.g., a conductor) that can have capacitance, can detect battery swelling with a cost-saving simple structure, and has very high versatility by being applicable regardless of an overall device structure or a battery shape or type, such as a cylindrical battery, a prismatic battery, and a pouch battery.

Aspects and features of the present disclosure are not limited to the aforementioned aspects and features, and other unmentioned aspects and features will be clearly understood by those skilled in the art from the following description.

### BRIEF DESCRIPTION OF THE DRAWINGS

The following drawings attached to the present specification illustrate embodiments of the present disclosure, and further describe aspects of the present disclosure together with the detailed description of the present disclosure. Thus, the present disclosure should not be construed as being limited to the drawings:

FIG. 1 schematically illustrates an electrode assembly of a secondary battery;

FIG. 2 schematically illustrates a configuration of a pouch-type secondary battery;

FIG. 3 illustrates a schematic external appearance configuration of a prismatic secondary battery;

FIG. 4 is a cross-sectional view of a cylindrical secondary battery;

FIG. 5 illustrates a battery cell with conductors according to embodiments of the present disclosure;

FIGS. 6A to 6D illustrate front views and plan views of a battery cell in a normal state and a swelling state according to embodiments of the present disclosure;

FIG. 7 illustrates a battery cell with conductors according to other embodiments of the present disclosure;

FIGS. 8A to 8D illustrate front views and plan views of a battery cell in a normal state and a swelling state according to other embodiments of the present disclosure;

FIGS. 9A and 9B illustrate a battery cell with conductors according to other embodiments of the present disclosure;

FIGS. 10A and 10B illustrate a capacitance change amount measurement unit according to embodiments of the present disclosure;

FIGS. 11A and 11B illustrate a connection configuration of a capacitance change amount measurement unit according to other embodiments of the present disclosure;

FIG. 12 illustrates a resonator circuit and a gain adjustment unit configured to sense a frequency change due to a capacitance change and to determine whether or not battery swelling has occurred according to embodiments of the present disclosure;

FIG. 13 illustrates a case including an additional circuit according to embodiments of the present disclosure;

FIG. 14 is a flowchart describing steps of a method for detecting battery swelling according to embodiments of the present disclosure;

FIG. 15 is a block diagram illustrating a computer system for implementing a method according to an embodiment of the present disclosure;

FIG. 16 is an exemplary view of a secondary battery module in which secondary batteries manufactured according to the present disclosure are arranged;

FIG. 17 is an exemplary view of a secondary battery pack including the secondary battery module illustrated in FIG. 16; and

FIG. 18 is a conceptual view of a vehicle including the secondary battery pack illustrated in FIG. 17.

### DETAILED DESCRIPTION

Hereinafter, embodiments of the present disclosure will be described, in detail, with reference to the accompanying drawings. The terms or words used in the present specification and claims are not to be limitedly interpreted as general or dictionary meanings and should be interpreted as meanings and concepts that are consistent with the technical idea of the present disclosure on the basis of the principle that an inventor can be his/her own lexicographer to appropriately define concepts of terms to describe his/her invention in the best way.

The embodiments described in this specification and the configurations shown in the drawings are only some of one or more embodiments of the present disclosure and do not represent all of the aspects of the present disclosure. Accordingly, it should be understood that there may be various equivalents and modifications that can replace or modify one or more embodiments described herein at the time of filing this application.

It will be understood that if an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, if a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” if describing embodiments of the present disclosure relates to “one or more embodiments of the present disclosure.” Expressions, such as “at least one of” and “any one of,” if preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” if used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

References to two compared elements, features, etc. As being “the same” may mean that they are “substantially the same.” Thus, the phrase “substantially the same” may include a case having a deviation that is considered low in the art, for example, a deviation of 5% or less. In addition, if a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may contact the upper (or lower) surface of the element, and another element may also be interposed between the element and the arbitrary element located on (or under) the element.

In addition, it will be understood that if a component is referred to as being “linked,” “coupled,” or “connected” to another component, the elements may be directly “coupled,” “linked” or “connected” to each other, or another component may be “interposed” between the components.”

Throughout the specification, if “A and/or B” is stated, it means A, B or A and B, unless otherwise stated. That is, “and/or” includes any or all combinations of a plurality of items enumerated. When “C to D” is stated, it means C or more and D or less, unless otherwise specified.

The terminology used herein is for the purpose of describing embodiments of the present disclosure and is not intended to limit the present disclosure.

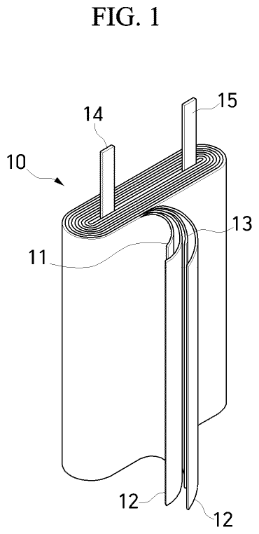

FIG. 1 schematically illustrates an electrode assembly accommodated in a case of a secondary battery.

An electrode assembly 10 may be formed by winding or stacking a stack of a first electrode plate 11, a separator 12, and a second electrode plate 13, which are formed as thin plates or films. When the electrode assembly 10 is a wound stack, a winding axis may be parallel to the longitudinal direction (e.g., the y direction) of the case 51. In other embodiments, the electrode assembly 10 may be a stack type rather than a winding type, and the shape of the electrode assembly 10 is not limited in the present disclosure. In addition, the electrode assembly 10 may be a Z-stack electrode assembly in which a positive electrode plate and a negative electrode plate are inserted into both sides of a separator, which is then bent into a Z-stack. In addition, one or more electrode assemblies may be stacked such that long sides of the electrode assemblies are adjacent to each other and accommodated in the case, and the number of electrode assemblies in the case is not limited in the present disclosure. The first electrode plate 11 of the electrode assembly may act as a negative electrode, and the second electrode plate 13 may act as a positive electrode. Of course, the reverse is also possible.

The first electrode plate 11 may be formed by applying a first electrode active material, such as graphite or carbon, to a first electrode current collector formed of a metal foil, such as copper, a copper alloy, nickel, or a nickel alloy. The first electrode plate 11 may include a first electrode tab 13 (e.g., a first uncoated portion) that is a region to which the first electrode active material is not applied. The first electrode tab 14 may be connected to an external first terminal (not shown). In some embodiments, when the first electrode plate 11 is manufactured, the first electrode tab 14 may be formed by being cut in advance to protrude to one side of the electrode assembly 10, or the first electrode tab 14 may protrude to one side of the electrode assembly 10 more than (e.g., farther than or beyond) the separator 12 without being separately cut.

The second electrode plate 13 may be formed by applying a second electrode active material, such as a transition metal oxide, on a second electrode current collector formed of a metal foil, such as aluminum or an aluminum alloy. The second electrode plate 13 may include a second electrode tab 15 (e.g., a second uncoated portion) that is a region to which the second electrode active material is not applied. The second electrode tab 15 may be connected to an external second terminal (not shown). In some embodiments, the second electrode tab 15 may be formed by being cut in advance to protrude to the other side (e.g., the opposite side) of the electrode assembly 10 when the second electrode plate 13 is manufactured, or the second electrode plate 13 may protrude to the other side of the electrode assembly more than (e.g., farther than or beyond) the separator 12 without being separately cut.

In some embodiments, the first electrode tab 14 may be located on the left side of the electrode assembly 10, and the second electrode tab 15 may be located on the right side of the electrode assembly 10. In other embodiments, the first electrode tab 14 and the second electrode tab 15 may be located on one side of the electrode assembly 10 in the same direction.

Here, for convenience of description, the left and right sides are defined according to the electrode assembly 10 as oriented in FIG. 1, and the positions thereof may change when the secondary battery is rotated left and right or up and down.

The separator 12 prevents a short-circuit between the first electrode plate 11 and the second electrode plate 13 while allowing movement of lithium ions therebetween. The separator 12 may be made of, for example, a polyethylene film, a polypropylene film, a polyethylene-polypropylene film, etc.

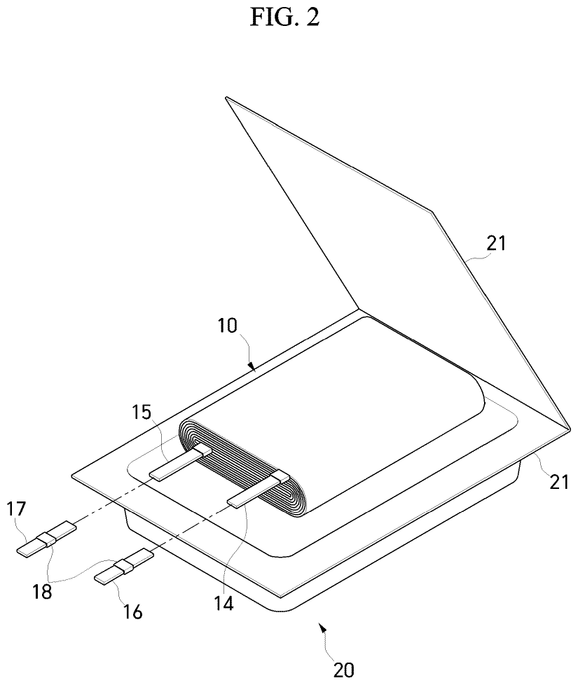

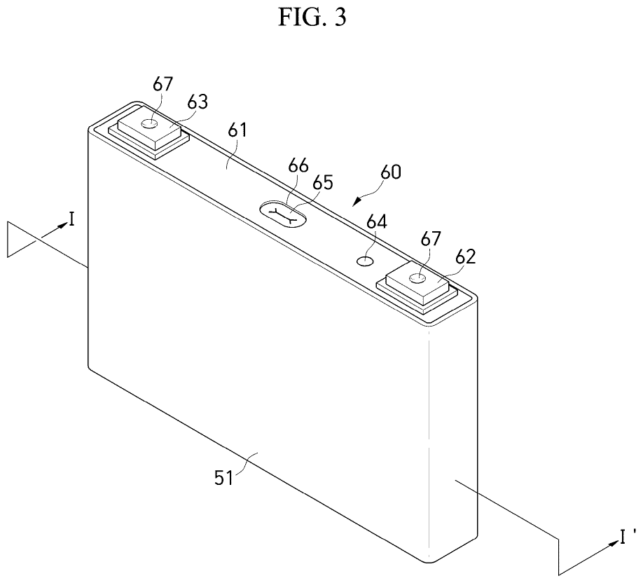

In some embodiments, the electrode assembly 10 may be accommodated in the case (not shown) along with an electrolyte. In the case of a pouch-type secondary battery, an electrode assembly 10 may be accommodated in a pouch made of flexible material in the form illustrated in FIG. 2. In the case of a prismatic secondary battery, an electrode assembly 10 may be accommodated in a prismatic metal casing in the form illustrated in FIG. 3.

FIG. 2 schematically illustrates the pouch-type secondary battery.

The pouch-type secondary battery includes an electrode assembly 10 and a pouch 20 that accommodates the electrode assembly 10

The electrode assembly 10 is the same as that illustrated in FIG. 1. The first electrode tab 14 and the second electrode tab 15 of the electrode assembly 10 may be electrically connected to respective external first and second terminal leads 16 and 17 by welding. Each of the first terminal lead 16 and the second terminal lead 17 may be attached with a tab film 18 for insulation from the pouch 20.

The pouch 20 may be sealed by having sealing parts 21 at the edges thereof come into contact with each other with accommodating the electrode assembly 10 therein, in which case the sealing may be achieved with the tab film 18 interposed between the sealing parts 21. The sealing parts 21 of the pouch 20 may each be made of a thermal fusion material that generally has weak adhesion to metal. Thus, it may be fused to the pouch 20 by interposing the thin tab film 18 between the sealing parts 21.

FIG. 3 illustrates a schematic external appearance configuration of a prismatic secondary battery.

A prismatic case 51 defines an overall appearance of the prismatic secondary battery, and may be made of a conductive metal, such as aluminum, aluminum alloy, or nickel-plated steel. In addition, the case 51 may provide a space for accommodating the electrode assembly 10 therein.

A cap assembly 60 may include a cap plate 61 that covers an opening of the case 51, and the case 51 and the cap plate 61 may be made of a conductive material. A first terminal 63 and a second terminal 62 may be electrically connected to the first electrode tab 14 and the second electrode tab 15 of the electrode assembly 10 inside the case, and may be installed to protrude outward through the cap plate 61.

The cap plate 61 may be equipped with an electrolyte injection port 64 formed to install a sealing plug, and a vent 66 formed with a notch 65 may be installed. The vent 66 is for discharging gas generated inside the secondary battery.

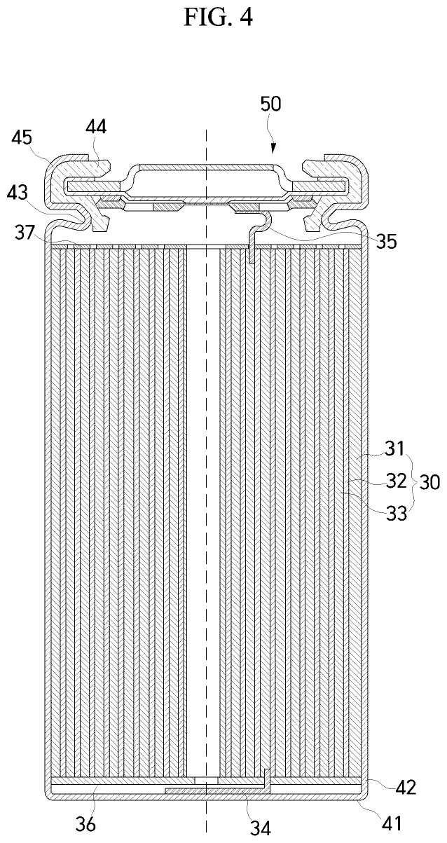

FIG. 4 is a cross-sectional view of a cylindrical secondary battery.

The cylindrical secondary battery includes an electrode assembly 30, a case accommodating the electrode assembly 30 and an electrolyte therein, a cap assembly 50 coupled to an opening of the case to seal the case, and an insulating plate 37 located between the electrode assembly 30 and the cap assembly 50 inside the case.

The electrode assembly 30 may include a separator 32 and a first electrode 33 and a second electrode 31 between which the separator 32 is located, and may be wound in a jelly-roll form.

The first electrode 33 includes a first substrate and a first active material layer located on the first substrate. A first lead tab 35 may extend outward from a first uncoated portion of the first substrate where the first active material layer is not located, and may be electrically connected to the cap assembly 50.

The second electrode 31 includes a second substrate and a second active material layer located on the second substrate. A second lead tab 34 may extend outward from a second uncoated portion of the second substrate where the second active material layer is not located, and may be electrically connected to the case. The first lead tab 35 and the second lead tab 34 may extend in opposite directions.

The first electrode 33 may serve as a positive electrode. In this case, the first substrate may be composed of, for example, aluminum foil, and the first active material layer may include, for example, a transition metal oxide. The second electrode 31 may serve as a negative electrode. In this case, the second substrate may be composed of, for example, copper foil or nickel foil, and the second active material layer may include, for example, graphite.

The separator 32 prevents a short-circuit between the first electrode 33 and the second electrode 31 while allowing movement of lithium ions therebetween. The separator 32 may be made of, for example, a polyethylene film, a polypropylene film, a polyethylene-polypropylene film, etc.

The case accommodates the electrode assembly 30 and the electrolyte, and forms the external appearance of the secondary battery together with the cap assembly 50. The case may have a substantially cylindrical body portion 42 and a bottom portion 41 connected to one side of the body portion 42. A beading part 43 deformed inwardly may be formed in the body portion 42, and a crimping part 45 bent inwardly may be formed at an open end of the body portion 42.

The beading part 43 can reduce or prevent movement of the electrode assembly 30 inside the case, and facilitate seating of a gasket 44 and the cap assembly 50. A crimping part 45 may firmly fix the cap assembly 50 by pressing the edge of the cap assembly 50 against the gasket 44. The case may be formed of iron plated with nickel, for example.

The cap assembly 50 may be fixed to the inside of the crimping part 45 through the gasket 44 to seal the case. The cap assembly 50 may include a cap up, a safety vent, a cap down, an insulating member, and a subplate, but is not limited to this example and may be variously modified.

The cap up may be located at the very top of the cap assembly 50. The cap up may include a terminal portion that protrudes convexly upward and is connected to an external circuit, and an outlet for discharging gas may be located around the terminal portion.

The safety vent may be located below the cap up. The safety vent may include a protrusion that protrudes convexly downward and is connected to the subplate, and at least one notch located around the protrusion.

When gas is generated due to overcharging or abnormal operation of the secondary battery, the protrusion may be deformed upward by pressure and separated from the subplate, while the safety vent may be cut along the notch. The cut safety vent may prevent the secondary battery from exploding by discharging gas to the outside.

The cap down may be located below the safety vent. The cap down may be formed with a first opening for exposing the protrusion of the safety vent and a second opening for discharging gas. The insulating member may be located between the safety vent and the cap down to insulate the safety vent and the cap down.

The subplate may be located below the cap down. The subplate may be fixed to a lower surface of the cap down to block the first opening of the cap down, and the protrusion of the safety vent may be fixed to the subplate. The first lead tab 35 pulled out from the electrode assembly 30 may be fixed to the subplate. Accordingly, the cap up, the safety vent, the cap down, and the subplate may be electrically connected to the first electrode 33 of the electrode assembly 30.

The insulating plate 37 may be located below the beading portion 43 to be in contact with the electrode assembly 30, and may be provided with a tab opening for pulling out the first lead tab 35. The cap assembly 50, which is electrically connected to the first electrode 33 by the first lead tab 35, may face the electrode assembly 30 with the insulating plate 37 interposed therebetween, and may maintain an insulated state from the electrode assembly 30 by the insulating plate 37. On the other hand, another insulating plate 36 may be included for insulation between the electrode assembly 30 and the bottom portion 41 of the case.

To prevent secondary battery explosion accidents, a method for detecting swelling being a sign of upcoming battery explosion according to the related art utilizes strain sensing.

The related art method for detecting strain includes attaching a thin-film strain sensor to an outer surface of a pouch based on the observation that a pouch film surrounding an electrode assembly is bent and deformed (e.g., strain) as swelling occurs from inside the battery. A metal based thin-film strain sensor has a relatively low gauge ratio in a range of about 2 to about 3 and has difficulty detecting a small change in strain (e.g., lacks sensitivity). Accordingly, a single crystal silicon-based thin-film strain sensor having a much higher gauge ratio than the metal-based strain sensor has been proposed. However, the structure and manufacturing method of the thin-film single crystal silicon-based strain sensor are complicated.

Embodiments of the present disclosure provide a method for detecting battery swelling based on capacitance sensing based on a relatively simple structure that is easy to implement and relatively low cost by using a material that can have capacitance, such as a conductor. The method for detecting battery swelling according to embodiments of the present disclosure can be applied regardless of an overall device structure or a battery type, such as a cylindrical type, a prismatic type, and a pouch type, and thus, is very versatile.

According to embodiments of the present disclosure, when a battery cell (also referred to simply as a cell) operates normally, the surface of the cell is maintained flat. However, when swelling occurs due to an abnormality in the cell, the distance between two conductors formed on the surface increases and, accordingly, the capacitance changes, such that the occurrence of the abnormality is determined by measuring the change in capacitance.

The shape of the conductor arranged in a conductor arrangement region can be configured in various shapes and is not limited to a specific shape or length.

Because the conductor can be formed with various materials other than metal and any material that can form capacitance can be utilized, the conductor is not limited to a specific material.

Various methods can be applied as a method for measuring capacitance changes. For example, frequency changes due to capacitance changes can be detected by using an oscillator circuit. For example, in a capacitor formed with conductors on a cell, when the distance between the conductors changes due to swelling, frequency changes due to capacitance changes can be detected. This is merely an example for assisting the understanding of those skilled in the art, and the present disclosure is not limited to this specific capacitance sensing method.

Dielectrics can be made of various materials, and various materials that are easy to manufacture, such as air, acrylic, glass, and rubber, can be used. However, when the material is included, because the manufacturing process becomes more complicated and the manufacturing cost increases, other materials may be omitted where possible.

The conductor is formed with a metal pattern or the like on a film rather than connected with individual lines, which facilitates manufacturing, and the film other than the metal pattern can act as a dielectric.

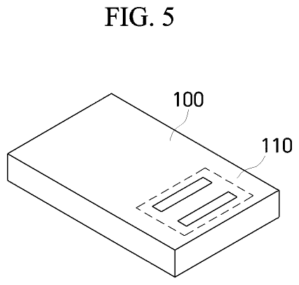

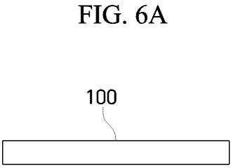

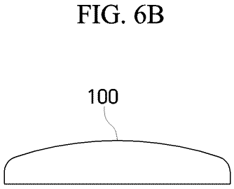

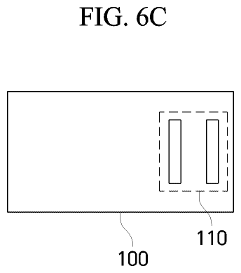

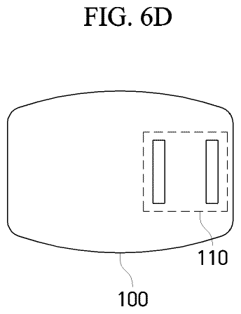

FIG. 5 illustrates a battery cell with conductors according to embodiments of the present disclosure, and FIGS. 6A to 6D illustrate front views and plan views of a battery cell in a normal state and a swelling state according to embodiments of the present disclosure. This is a schematic (or simplified) illustration for describing the arrangement of conductors and may differ from the actual arrangement.

Referring to the front view shown in FIG. 6B compared to the normal state shown in FIG. 6A, when swelling occurs, bending occurs upwardly (or sideways), and due to this bending, as illustrated in the plan view shown in FIG. 6D compared to that shown in FIG. 6C, the distance between two conductors formed in a first region 110 of a battery cell 100 increases. When the distance between the two conductors increases, a difference in capacitance therebetween occurs compared to the capacitance in the normal state, and whether or not swelling has occurred can be detected by detecting the difference (or change) in capacitance. Capacitance is calculated based on the relative permittivity and the area and distance of the conductive plate and is proportional to the area and inversely proportional to the distance.

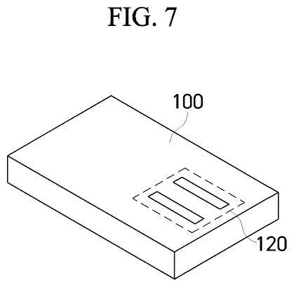

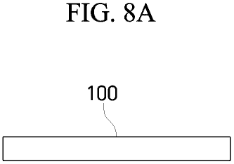

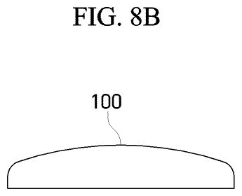

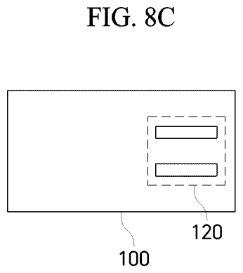

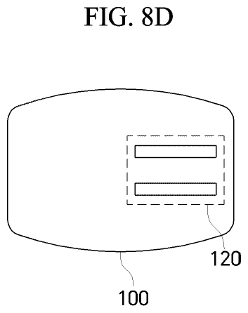

FIG. 7 illustrates a battery cell with conductors according to other embodiments of the present disclosure, and FIGS. 8A to 8D illustrate front views and plan views of a battery cell in a normal state and a swelling state according to other embodiments of the present disclosure. As described above, this is a schematic illustration for describing the arrangement of conductors and may differ from the actual arrangement.

Referring to the front view shown in FIG. 8B compared to the normal state shown in FIG. 8A, when swelling occurs, bending occurs upwardly (or sideways), and due to this bending, as illustrated in the plan view shown in FIG. 8D compared to FIG. 8C, the distance between two conductors formed in a second region 120 of a battery cell 100 increases. Because the length of the conductor increases and a difference occurs compared to the capacitance in the normal state, whether or not swelling has occurred can be detected by detecting the difference in capacitance.

In the embodiment illustrated in FIGS. 5 and 6, the distance between the two conductors arranged in the first region 110 increases and the capacitance value gradually decreases, while in the other embodiment illustrated in FIGS. 7 and 8, an area of the two conductors arranged in the second region 120 increases and the capacitance value gradually increases. That is, although the structures in these embodiments are similar, opposite results (e.g., opposite changes in capacitance) are derived depending on the direction of arrangement (e.g., horizontal/vertical).

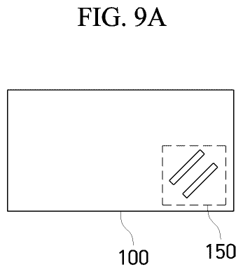

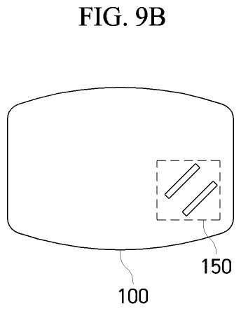

FIGS. 9A and 9B illustrate a battery cell with conductors according to other embodiments of the present disclosure. FIG. 9A is a front view illustrating a battery cell with conductors according to other embodiments of the present disclosure in a normal state, and FIG. 9B is a plan view illustrating the battery cell in a swelled state. Referring to FIGS. 9A and 9B, when swelling occurs, the bending of the battery changes the most at the edges of the four sides thereof. Accordingly, when the conductors are placed in a corresponding region 150, the effect related to the capacitance change amount measurement is the greatest.

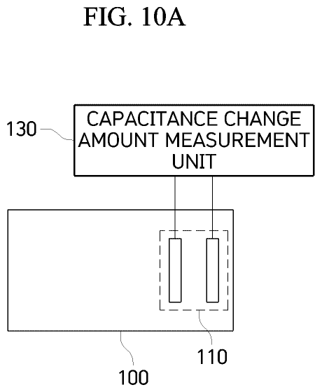

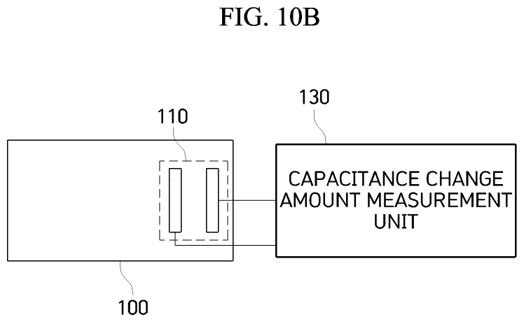

FIGS. 10A and 10B illustrate a capacitance change amount measurement unit according to embodiments of the present disclosure.

As illustrated in FIGS. 10A and 10B, conductors placed in a first region 110 (FIG. 10 illustrates the conductor arrangement according to an embodiment described above) are connected to a capacitance change amount measurement unit 130, and the capacitance change amount measurement unit 130 measures a capacitance change amount that changes according to a change in distance (e.g., according to a change in area in the case of the conductor arrangement according to the embodiments described with reference to FIGS. 7 and 8). In such an embodiment, a method of connecting to the capacitance change amount measurement unit 130 may utilize various methods and is not limited. According to embodiments of the present disclosure, the connection between the conductors and the capacitance change amount measurement unit 130 is an electrical connection, is sufficient if it can confirm a capacitance change, and is not limited to a single connection method.

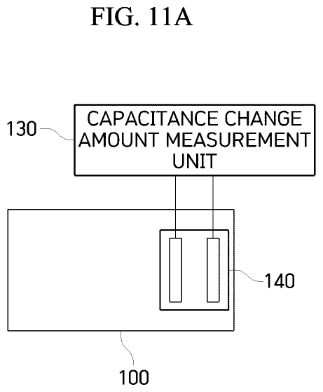

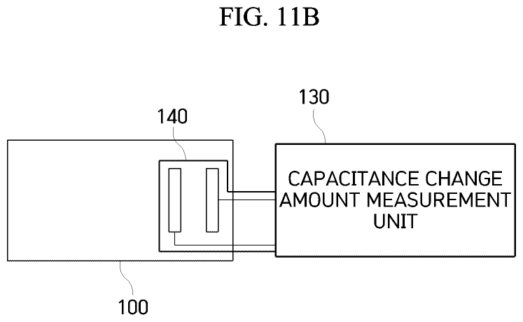

FIGS. 11A and 11B illustrate a connection of a capacitance change amount measurement unit according to other embodiments of the present disclosure.

A film 140 including conductors may be used with the conductors therebetween or with the conductors placed thereon, and is not limited to a specific shape, pattern, length, and the like.

When the film 140 has a shape that wraps (e.g., surrounds or extends around) the conductors, the film between the conductors acts as a dielectric. In such an embodiment, because the dielectric contributes to the formation of capacitance, a capacitance change amount may be different accordingly.

Accordingly, various types of films may be used to adjust a capacitance change amount depending on the application, and the film is not limited to a specific single type.

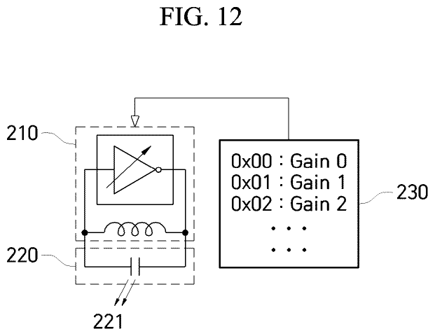

FIG. 12 illustrates a resonator circuit and a gain adjustment unit configured to sense (or measure or determine) a frequency change due to a capacitance change and determine whether or not battery swelling has occurred according to embodiments of the present disclosure.

FIG. 12 illustrates a variable resonator circuit, but according to embodiments of the present disclosure, an LC resonator circuit may be formed by a resonator circuit unit including an integrated circuit or the like, a capacitor implementation unit, and a conductor included in the capacitor implementation unit. For example, a frequency is determined by inductors (L) and capacitors (C), and resonance is maintained by an amplifier (Amp.). As described above, the amplifier and the inductor can be implemented inside an integrated circuit (IC), and the capacitor implementation unit can be implemented outside the IC and attached to a battery according to embodiments of the present disclosure.

The frequency of the resonator is determined by L and C as in Equation 1 below.

$$f = \frac{1}{2 π \sqrt{LC}} \qquad Equation 1$$

L is implemented inside the IC and has a fixed value, and C is determined by the two conductors attached to the battery. In a normal state when no swelling has occurred, a capacitance value is fixed and a constant frequency is determined, but when swelling occurs and the distance between the conductors increases, the capacitance value decreases and the frequency increases. This deviation (or lack of deviation) is used to determine whether or not the battery swelling has occurred. The circuit described above is an example of an LC resonator using a capacitor, but the present disclosure is not limited to this circuit.

In the resonator circuit, the amplifier maintains oscillation. Assuming an ideal inductor L and capacitor C, incoming energy is exchanged and resonance is maintained, but actually, because there is a resistance component, the resonance is not maintained, the magnitude of a waveform gradually decreases, and the resonance disappears. The amplifier is used to maintain oscillation and is generally expressed as a negative resistor and is expressed as an opposite component-R of an actual resistance component R.

When a capacitor is implemented through a conductor, a resistance component varies depending on the application. For example, when the resistance is larger than the expected design, because the negative resistance component of an amplifier does not offset a large resistance component, the resonance may not be maintained.

Referring to FIG. 12, an adaptive amplifier can be used instead of a fixed amplifier and includes an adaptive resonator circuit unit 210, a capacitor implementation unit 220, a conductor 221 included in the capacitor implementation unit 220, and a gain adjustment unit 230.

According to embodiments of the present disclosure, the gain adjustment unit 230 is provided to adjust the gain Gain of the amplifier in relation to the configuration of the adaptive amplifier, and a corresponding gain can be provided for each application to which the system is applied.

After an additional circuit is added to determine whether or not a resonator is operating, when it is determined that the resonator is not operating, the gain may be automatically adjusted to control the resonator to operate.

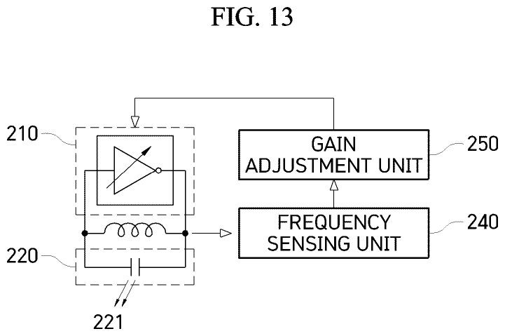

FIG. 13 illustrates a variable resonator circuit including an additional circuit (e.g., a frequency sensing unit) according to other embodiments of the present disclosure.

Referring to FIG. 13, the gain can be adjusted by adjusting a control bit corresponding to each application, and the amplifier includes a frequency sensing unit 240 that is an additional circuit for determining whether or not the resonator is operating, and automatically adjusts the gain through a gain adjustment unit 250 by recognizing a situation in which the resonator is not operating, and gradually increases the gain from a situation in which no resonance occurs until resonance occurs, and does not further increase the gain once resonance is recognized (or measured).

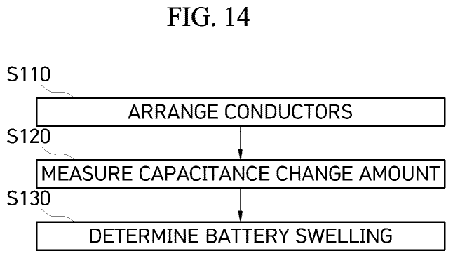

FIG. 14 is a flowchart describing steps of a method for detecting battery swelling according to embodiments of the present disclosure.

The method for detecting battery swelling according to embodiments of the present disclosure includes step S110 of arranging conductors in a region (e.g., a region of a battery case) to detect battery swelling, step S120 of measuring a capacitance change amount according to a change in the conductors, and step S130 of determining whether or not the battery swelling has occurred by using a result of measuring the capacitance change amount.

According to one embodiment, in step S110, the conductors are arranged in a first region, and in step S120, the capacitance change amount resulting from an increase in the distance between the conductors arranged in the first region is measured.

According to another embodiment, in step S110, the conductors are arranged in a second region, and in step S120, the capacitance change amount according to an increase in an area of the conductors arranged in the second region is measured.

According to various embodiments, in step S110, the conductors are arranged in at an edge region of a battery cell in consideration of the battery swelling.

According to various embodiments, in step S110, a film including the conductors is arranged in the region (e.g., the first region, the second region, the edge region, etc.).

The type of film is determined in consideration of adjusting the capacitance change amount according to the application.

The method for detecting battery swelling according to embodiments of the present disclosure may further include a step of sensing whether or not a resonator connected to a capacitance implementation unit formed of the conductors is operating, and in such an embodiment, the gain of a variable amplifier is adjusted in consideration of a result of sensing whether or not the resonator is operating.

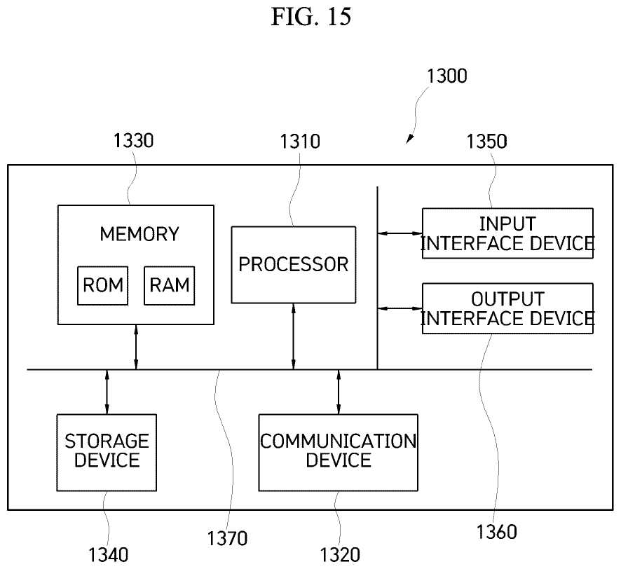

FIG. 15 is a block diagram illustrating a computer system for implementing a method according to an embodiment of the present disclosure.

Referring to FIG. 15, the computer system 1300 may include at least one of a processor 1310, a memory 1330, an input interface device 1350, an output interface device 1360, and a storage device 1340 communicating with one another through a bus 1370. The computer system 1300 may also include a communication device 1320 coupled to a network. The processor 1310 may be a central processing unit (CPU) or a semiconductor device that executes instructions stored in the memory 1330 or the storage device 1340. The memory 1330 and the storage device 1340 may include various types of volatile or nonvolatile storage media. For example, the memory may include a read-only memory (ROM) and a random access memory (RAM). In embodiments of the present disclosure, the memory may be located inside or outside the processor, and may be connected to the processor through various known means. The memory is various types of volatile or nonvolatile storage media, and for example, may include a read-only memory (ROM) or a random access memory (RAM).

A system for detecting battery swelling according to embodiments of the present disclosure includes the memory 1330 storing a program for measuring a capacitance change amount by using conductors arranged on a battery surface, and the processor 1310 executing the program, and the processor 1310 detects battery swelling by measuring the capacitance change amount.

The conductors are arranged in a region, and the distance between the conductors changes when battery swelling occurs.

As another example, the conductors are arranged in the region, and an area of the conductors changes when the battery swelling occurs.

The processor 1310 senses whether or not a resonator connected to a capacitance implementation unit formed of the conductors is operating and adjusts the gain of a variable amplifier.

Accordingly, embodiments of the present disclosure may be implemented as a method implemented in a computer or a non-transitory computer-readable medium storing computer-executable instructions. In an embodiment, when executed by the processor, computer-readable instructions may perform a method according to at least one aspect of the present disclosure.

The communication device 1320 may transmit or receive wired signals or wireless signals.

Additionally, the method according to an embodiment of the present disclosure may be implemented in the form of program instructions that can be executed through various computer means and recorded on a computer-readable medium.

The computer-readable medium may include program instructions, data files, data structures, etc., singly or in combination. The program instructions recorded on the computer-readable medium may be specially designed and configured for embodiments of the present disclosure, or may be known and usable by those skilled in the art of computer software. Computer-readable recording media may include a hardware device configured to store and perform program instructions. For example, the computer-readable recording media may be magnetic media such as hard disks, floppy disks, and magnetic tapes, optical media such as CD-ROMs and DVDs, magneto-optical media such as floptical disks, ROM, RAM, flash memory, etc. The program instructions may include not only machine language codes such as that generated by a compiler, but also high-level language codes that can be executed by a computer through an interpreter, etc.

Hereinafter, any material that may be usable for the secondary battery according to the present disclosure will be described.

As the positive electrode active material, a compound capable of reversibly intercalating/deintercalating lithium (e.g., a lithiated intercalation compound) may be used. For example, at least one of a composite oxide of lithium and a metal selected from cobalt, manganese, nickel, and combinations thereof may be used.

The composite oxide may be a lithium transition metal composite oxide, and examples thereof may include a lithium nickel-based oxide, a lithium cobalt-based oxide, a lithium manganese-based oxide, a lithium iron phosphate-based compound, a cobalt-free nickel-manganese-based oxide, or a combination thereof.

As an example, a compound represented by any one of the following formulas may be used: LiₐA_{1-b}X_{b}O_{2-c}D_{c} (0.90≤a≤1.8, 0≤b≤0.5, 0≤c≤0.05); LiₐMn_{2-b}X_{b}O_{4-c}D_{c} (0.90≤a≤1.8, 0≤b≤0.5, 0≤c≤0.05); LiₐNi_{1-b-c}Co_{b}X_{c}O_{2-α}D_{α} (0.90≤a≤1.8, 0≤b≤0.5, 0≤c≤0.5, 0≤c≤2); LiₐNi_{1-b-c}Mn_{b}X_{c}O_{2-α}D_{α} (0.90≤a≤1.8, 0≤b≤0.5, 0≤c≤0.5, 0≤α≤2); LiₐNi_{b}Co_{c}L¹_{d}GₑO₂ (0.90≤a≤1.8, 0≤b≤0.9, 0≤c≤0.5, 0≤d≤0.5, 0≤e≤0.1); LiₐNiG_{b}O₂ (0.90≤a≤1.8, 0.001≤b≤0.1); LiₐCoG_{b}O₂ (0.90≤a≤1.8, 0.001≤b≤0.1); LiₐMn_{1-b}G_{b}O₂ (0.90≤a≤1.8, 0.001≤b≤0.1); LiₐMn₂G_{b}O₄ (0.90≤a≤1.8, 0.001≤b≤0.1); LiₐMn_{1-g}G_{g}PO₄ (0.90≤a≤1.8, 0≤g≤0.5); Li_{(3-f)} Fe₂(PO₄)₃ (0≤f≤2); and LiₐFePO₄ (0.90≤a≤1.8).

In the above formulas: A is Ni, Co, Mn, or a combination thereof; X is Al, Ni, Co, Mn, Cr, Fe, Mg, Sr, V, a rare earth element, or a combination thereof; D is O, F, S, P, or a combination thereof; G is Al, Cr, Mn, Fe, Mg, La, Ce, Sr, V, or a combination thereof; and L1 is Mn, Al, or a combination thereof.

A positive electrode for a lithium secondary battery may include a current collector and a positive electrode active material layer formed on the current collector. The positive electrode active material layer may include a positive electrode active material and may further include a binder and/or a conductive material.

The content of the positive electrode active material is in a range of about 90 wt % to about 99.5 wt % on the basis of 100 wt % of the positive electrode active material layer, and the content of the binder and the conductive material is in a range of about 0.5 wt % to about 5 wt %, respectively, on the basis of 100 wt % of the positive electrode active material layer.

The current collector may be aluminum (Al) but is not limited thereto.

The negative electrode active material may include a material capable of reversibly intercalating/deintercalating lithium ions, lithium metal, an alloy of lithium metal, a material capable of being doped and undoped with lithium, or a transition metal oxide.

The material capable of reversibly intercalating/deintercalating lithium ions may be a carbon-based negative electrode active material, which may include, for example, crystalline carbon, amorphous carbon, or a combination thereof. Examples of the crystalline carbon may include graphite, such as natural graphite or artificial graphite, and examples of the amorphous carbon may include soft carbon, hard carbon, a pitch carbide, a meso-phase pitch carbide, sintered coke, and the like.

A Si-based negative electrode active material or a Sn-based negative electrode active material may be used as the material capable of being doped and undoped with lithium.

The Si-based negative electrode active material may be silicon, a silicon-carbon composite, SiOx (0<x<2), a Si-based alloy, or a combination thereof.

The silicon-carbon composite may be a composite of silicon and amorphous carbon. According to one embodiment, the silicon-carbon composite may be in the form of a silicon particle and amorphous carbon coated on the surface of the silicon particle.

The silicon-carbon composite may further include crystalline carbon. For example, the silicon-carbon composite may include a core including crystalline carbon and silicon particle and an amorphous carbon coating layer on the surface of the core.

A negative electrode for a lithium secondary battery may include a current collector and a negative electrode active material layer disposed on the current collector. The negative electrode active material layer may include a negative electrode active material and may further include a binder and/or a conductive material.

For example, the negative electrode active material layer may include about 90 wt % to about 99 wt % of a negative electrode active material, about 0.5 wt % to about 5 wt % of a binder, and about 0 wt % to about 5 wt % of a conductive material.

A non-aqueous binder, an aqueous binder, a dry binder, or a combination thereof may be used as the binder. When an aqueous binder is used as the negative electrode binder, a cellulose-based compound capable of imparting viscosity may be further included.

As the negative electrode current collector, one selected from copper foil, nickel foil, stainless steel foil, titanium foil, nickel foam, copper foam, conductive metal-coated polymer substrate, and combinations thereof may be used.

An electrolyte for a lithium secondary battery may include a non-aqueous organic solvent and a lithium salt.

The non-aqueous organic solvent acts as a medium through which ions involved in the electrochemical reaction of the battery can move.

The non-aqueous organic solvent may be a carbonate-based, an ester-based, an ether-based, a ketone-based, an alcohol-based solvent, an aprotic solvent, and may be used alone or in combination of two or more.

Depending on the type of lithium secondary battery, a separator may be present between the first electrode plate (e.g., the negative electrode) and the second electrode plate (e.g., the positive electrode). As the separator, polyethylene, polypropylene, polyvinylidene fluoride, or a multilayer film of two or more layers thereof may be used.

The separator may include a porous substrate and a coating layer including an organic material, an inorganic material, or a combination thereof on one or both surfaces of the porous substrate.

The organic material may include a polyvinylidene fluoride-based polymer or a (meth)acrylic polymer.

The inorganic material may include inorganic particles selected from Al₂O₃, SiO₂, TiO₂, SnO₂, CeO₂, MgO, NiO, CaO, GaO, ZnO, ZrO₂, Y₂O₃, SrTiO₃, BaTiO₃, Mg(OH)₂, boehmite, and combinations thereof but is not limited thereto.

The organic material and the inorganic material may be mixed in one coating layer or may be in the form of a coating layer containing an organic material and a coating layer containing an inorganic material that are laminated on each other.

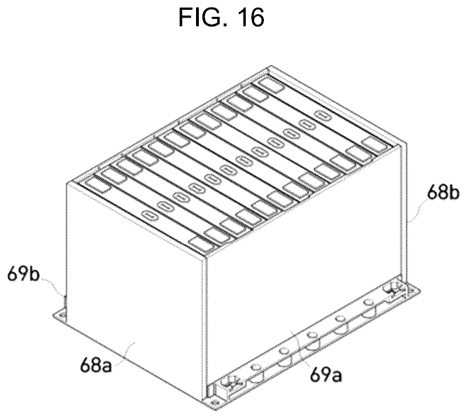

FIG. 16 is an exemplary view of a secondary battery module in which secondary batteries manufactured according to the present disclosure are arranged. With the increase in secondary battery capacity for driving electric vehicles etc., a secondary battery module may be manufactured by arranging and connecting a plurality of secondary battery cells transversely and/or longitudinally. The plurality of secondary batteries may be arranged in a space defined by a pair of facing end plates 68a and 68b and a pair of facing side plates 69a and 69b. The secondary batteries may be designed appropriately in arrangement (direction) and number to obtain desired voltage and current specifications.

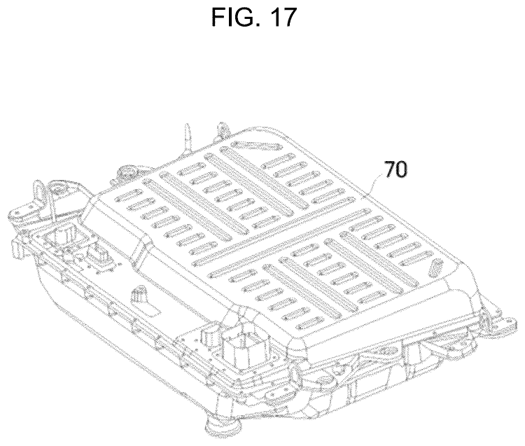

FIG. 17 is an exemplary view schematically showing the configuration of a battery pack 70 according to embodiments of the present disclosure. Referring to FIG. 17, a battery pack 70 may include an assembly to which individual batteries are electrically connected and a pack housing accommodating the same. In the drawings, for convenience of illustration, components including a bus bar, a cooling unit, external terminals for electrically connecting batteries, etc., are not shown.

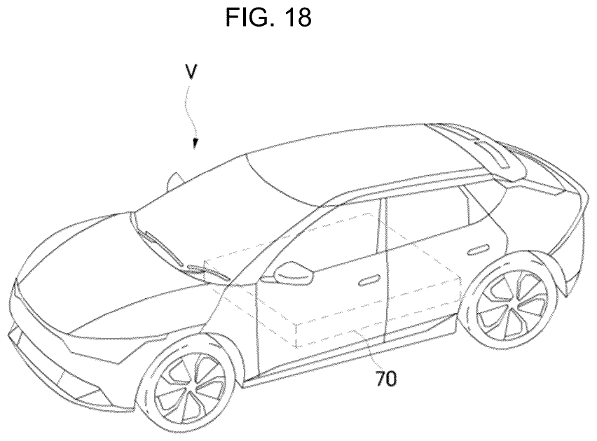

The battery pack 70 may be mounted on (or in) a vehicle. The vehicle may be, for example, an electric vehicle, a hybrid vehicle, or a plug-in hybrid vehicle. The vehicle may be a four-wheeled vehicle or a two-wheeled vehicle but is not limited thereto. FIG. 18 shows a vehicle V which includes the battery pack 70 shown in FIG. 17 on the lower body thereof. The vehicle V may operate by (e.g., may be powered by) receiving power from the battery pack 70.

Although the present disclosure has been described above with respect to embodiments thereof, the present disclosure is not limited thereto. Various modifications and variations can be made thereto by those skilled in the art within the spirit of the present disclosure and the equivalent scope of the appended claims.

However, aspects and features of the present disclosure are not limited to the above-described aspects and features, and other aspect and features not mentioned will be clearly understood by those skilled in the art from the above description.

What is claimed is:

1. A method for detecting battery swelling, the method comprising:
arranging conductors in a region of a battery cell to detect swelling of the battery cell;
measuring a capacitance change amount when an arrangement of the conductors changes; and
determining whether or not battery swelling has occurred by using a result of the measuring of the capacitance change amount.

2. The method for detecting battery swelling as claimed in claim 1, wherein the conductors are arranged in a first region, and
wherein the capacitance change amount according to an increase in a distance between the conductors arranged in the first region is measured.

3. The method for detecting battery swelling as claimed in claim 1, wherein the conductors are arranged in a second region, and
wherein the capacitance change amount according to an increase in an area of the conductors arranged in the second region is measured.

4. The method for detecting battery swelling as claimed in claim 1, wherein the region at where the conductors are arranged is an edge region of the battery cell.

5. The method for detecting battery swelling as claimed in claim 1, wherein a film comprising the conductors is arranged in the region.

6. The method for detecting battery swelling as claimed in claim 5, wherein the film is configured to adjust the capacitance change amount according to an application.

7. The method for detecting battery swelling as claimed in claim 1, further comprising sensing whether or not a resonator connected to a capacitance implementation unit formed of the conductors is operating.

8. The method for detecting battery swelling as claimed in claim 7, further comprising adjusting a gain of a variable amplifier in consideration of a result of the sensing of whether or not the resonator is operating.

9. A system for detecting battery swelling comprising:
memory configured to store a program for measuring a capacitance change amount by using conductors arranged on a surface of a battery cell; and
a processor configured to execute the program,
wherein the processor is configured to detect battery swelling by measuring the capacitance change amount.

10. The system for detecting battery swelling as claimed in claim 9, wherein the conductors are arranged in a region of the surface of the battery cell, and
wherein a distance between the conductors changes when battery swelling occurs.

11. The system for detecting battery swelling as claimed in claim 9, wherein the conductors are arranged in a region of the surface of the battery cell, and
wherein an area of the conductors changes when battery swelling occurs.

12. The system for detecting battery swelling as claimed in claim 9, wherein the processor is configured to determine whether or not a resonator connected to a capacitance implementation unit formed of the conductors is operating and to adjust a gain of a variable amplifier in response thereto.
